(19) United States
(12) Patent Application Publication
(10) Pub. No.: US 2005/0212067 A1
(43) Pub. Date: Sep. 29, 2005

(54) Microelectromechanical devices with lubricants and getters formed thereon

(76) Inventors: Robert Duboc, Menlo Park, CA (US); Jim Dunphy, San Jose, CA (US)

Correspondence Address: REFLECTIVITY, INC., 350 POTRERO AVENUE, SUNNYVALE, CA, 94085, US

(21) Appl. No.: 10/810,076

(22) Filed: Mar. 26, 2004

(51) Int. Cl. H01L 23/02; H01L 29/84

(52) U.S. Cl. 257/415; 257/680; 257/682

(57) ABSTRACT

The present invention provides a packaged microelectromechanical device having a plurality of deflectable elements formed on a substrate that has a getter and/or a lubricant disposed thereon. The substrate can be a glass substrate or a semiconductor wafer. The lubricant and/or getter can be disposed on the substrate or held by one or more containers that are attached to the substrate.

### TECHNICAL FIELD OF THE INVENTION

The present invention is related generally to the art of microelectromechanical systems, and, more particularly, to lubricating surfaces of the microstructures and maintaining an inert ambient in the microstructure.

### BACKGROUND OF THE INVENTION

Microstructures, such as microelectromechanical devices, have many applications in basic signal transduction. For example, a spatial light modulator based on a microelectromechanical device steers light in response to electrical or optical signals. Such a modulator can be a part of a communication device or an information display.

A major factor that limits the reliability and widespread use of microelectromechanical devices is adhesion. Adhesion is a result of the dominance of surface and interfacial forces, such as capillary, chemical bonding, electrostatic, and van der Waals forces, over mechanical forces which tend to separate microelectromechanical components. When mechanical restoring forces cannot overcome adhesive forces, the microelectromechanical devices are said to suffer from stiction. Stiction failures in contacting microstructures, such as micromirror devices, can occur after the first contacting event (often referred to as initial stiction), or as a result of repeated contacting events (often referred to as in-use stiction). Initial stiction is often associated with surface contamination (e.g., residues of bonding materials or photoresist), or with high energy of contacting surfaces (e.g., clean oxidized silicon or metallic surfaces). For the case of in-use stiction, each time one part of the microstructure (e.g. mirror plate of a micromirror device) touches the other (e.g. stopping mechanism) or the substrate, the contact force grows and ultimately becomes too large for the restoring force to overcome. In this case, the device remains in one state indefinitely. This phenomenon can arise from a variety of underlying mechanisms, such as contact area growth, creation of high-energy surface by micro-wear, surface charge separation etc. An approach to reduce stiction is to lubricate surfaces of microstructures.

### SUMMARY OF THE INVENTION

In an embodiment of the invention, a packaged microelectromechanical device is disclosed, comprising: a deflectable element on a substrate; a getter material and/or a lubricant material disposed on the substrate; and a package having the substrate with the deflectable element.

In another embodiment of the invention, a microelectromechanical device is disclosed, comprising: a substrate; a deflectable element attached to a deformable element held by the substrate; and a carrier disposed on the substrate, wherein the carrier adsorbs a lubricant material that is operable for lubricating a surface of the device, said carrier is operable to desorb the adsorbed lubricant upon a variation of the environment in which the device is operated.

### BRIEF DESCRIPTION OF DRAWINGS

While the appended claims set forth the features of the present invention with particularity, the invention, together with its objects and advantages, may be best understood from the following detailed description taken in conjunction with the accompanying drawings of which:

FIG. 1 is a perspective view of an exemplary spatial light modulator having an array of micromirrors formed on a glass substrate on which a getter and lubricant material is disposed thereon;

FIG. 2 is a perspective view an exemplary micromirror array device of the micromirror array in FIG. 1;

FIG. 3 is a cross-sectional view of the spatial light modulator of FIG. 1;

FIG. 4a is an exploded cross-sectional view of a substrate having a getter material and a lubricant material disposed thereon according to an embodiment of the invention;

FIG. 4b is an exploded cross-sectional view of a substrate having a getter material and a lubricant material disposed thereon according to another embodiment of the invention;

FIG. 4c is an exploded cross-sectional view of a substrate having a getter material and a lubricant material disposed thereon according to yet another embodiment of the invention;

FIG. 4d is an exploded cross-sectional view of a substrate having a getter material and a lubricant material disposed thereon according to yet another embodiment of the invention;

FIG. 4e is an exploded cross-sectional view of a substrate having a getter material and a lubricant material disposed thereon according to yet another embodiment of the invention;

FIG. 4f is an exploded cross-sectional view of a substrate having a getter material and a lubricant material disposed thereon according to yet another embodiment of the invention;

FIG. 4g illustrates an exemplary substrate of the spatial light modulator in FIG. 1, the substrate having a trench and/or a cavity for holding the getter and/or the lubricant materials;

FIG. 5 is a perspective of an exemplary spatial light modulator package; and

FIG. 6 is a perspective of another exemplary spatial light modulator package.

### DETAILED DESCRIPTION OF THE EMBODIMENTS

The present invention discloses a microelectromechanical device having a plurality of deflectable elements formed on a substrate that has a getter and a lubricant disposed thereon. The substrate can be a glass substrate or a semiconductor wafer. The lubricant and getter can be disposed on the substrate or held by one or more containers that are attached to the substrate. The lubricant and/or the getter can also be disposed in a trench and/or a cavity formed on the substrate. Alternatively, the getter can be used as a carrier for holding the lubricant.

The microelectromechanical device can be any of a variety of types, such as micromirrors, micro-engines, micro-sensors and micro-actuators. In the following, the present invention will be discussed with reference to a spatial light modulator having an array of micromirrors. It will be appreciated by those skilled in the art that the following discussion is for demonstration purposes only; and should not be interpreted as a limitation. Instead, variations to the following examples without departing from the spirit of the invention are also applicable.

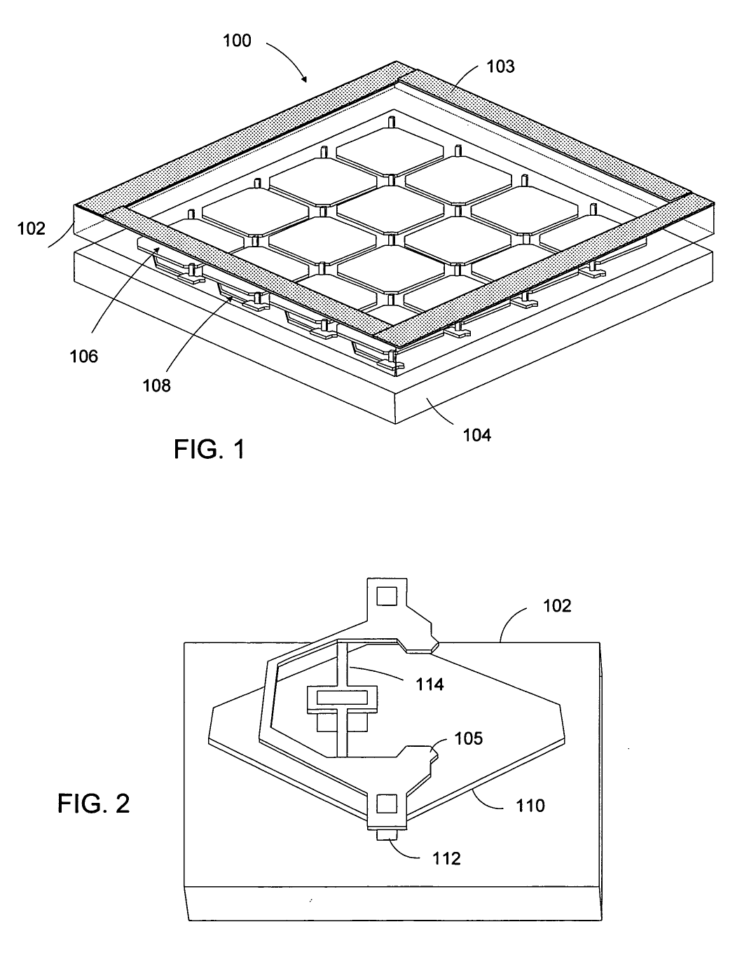

Turning to the drawings, FIG. 1 illustrates a perspective view of a portion of an exemplary spatial light modulator. In its basic configuration, spatial light modulator 100 comprises micromirror array 106 formed on glass substrate 102 that is transmissive to visible light. The micromirrors are individually deflectable by an array of electrodes and circuitry 108 formed on semiconductor substrate 104 disposed proximate to the glass substrate. In general, the spatial light modulator comprises thousands or millions of individually deflectable micromirrors. The micromirror may be of any suitable configuration, such as that shown in FIG. 2. As shown in FIG. 2, a mirror plate 110 is held on glass substrate 102 and connected to the glass substrate via posts 112. Mirror plate 110 is attached to the hinge such that the mirror plate is operable to rotate on the substrate. There are many other alternatives to the spatial light modulator in FIG. 1 and micromirror in FIG. 2. For example, the micromirror array of the spatial light modulator can be formed on a semiconductor substrate (e.g. substrate 104) having thereon an array of electrodes and circuitry (with or without a protection glass bonded thereto). The micromirror of FIGS. 1 and 2 are fabricated such that the hinge is underneath the mirror plate and hidden from the incident light traveling through the glass substrate. This configuration benefits the display performance. Specifically, the contrast ratio of the displayed images can be improved from removal of the light scattering by the hinge. Alternatively, a micromirror may have a hinge and mirror plate, wherein the hinge is exposed to the incident light. The mirror plate can take any desired shapes in addition to four sided shape as shown in the figures. The mirror plate can be attached to the hinge such that the rotation of the mirror plate is asymmetrical or symmetrical. Specifically, the mirror plate can be attached to the hinge at an attachment location that is not at the center of the mirror plate such that the hinge is parallel to but offset to a diagonal of the mirror plate when viewed from above. For improving the performance of the micromirror, other structures, such as a stopping mechanism (e.g. stopper 105 in FIG. 2) for limiting the rotation of the mirror plate can be provided.

In operation, in-use stiction may occur in the contact area of the mirror plate and stopping mechanism (e.g. a substrate, an electrode, or a stopper) of the micromirror device. In order to prevent such in-use stiction, the micromirror device, especially the contact area, is lubricated with a lubricant material that coats or physically reacts with the surface molecules of the contact area. In accordance with the invention, the lubricant can be liquid (or paste) or solid. The lubricant may have a high boiling point (e.g. 100° C. or higher) or low vapor pressure such that the lubricant does not condense at low temperature or fully evaporate at high temperatures (e.g. 30° C. or more or 70° C. or more, or even 100° C. or more) (the high and temperature refer to the storage and operating range of the micromirror device). The lubricant is desired to be stable at a high temperature, such as 200° C. or higher. The viscosity of the lubricant in liquid phase can be of from 1 cP to 5000 cP. However, any desired lubricant can be used.

As an example, the lubricant can be a perfluoropolyether with molecular weight of from 500 to 5000. The lubricant can also be a perfluorinated hydrocarbon having 30 carbons or less, such as an alkane, an amine, an alcohol, an ether, atriazine, or a glycols. Other suitable lubricants are also applicable. The lubricant may be mixed with other materials, such as a diluent to form a lubricant solution. The diluent is preferably chemically stable at a temperature of 200° C. or higher. An exemplary diluent is a perfluorinated hydrocarbon having 20 carbons or less.

The spatial light modulator may be operated in an environment having unexpected gases, moisture or particles (e.g. due to package leaks) which may degrade the performance of the spatial light modulator or cause device failure. This problem can be solved by providing a getter (or getters) to the spatial light modulator for absorbing the gases, moisture, and/or the particles in the environment in which the micromirrors of the spatial light modulator are operated.

The lubricant (or the lubricant solution) for lubricating the surfaces of the micromirrors and the getter(s) for absorbing the gases, moisture, and particles can be disposed at any desired location in the spatial light modulator. As an example of the invention, the lubricant and the getter are disposed on the substrate on which the deflectable elements (e.g. the micromirrors of the spatial light modulator) of the microelectromechanical devices are formed; and the lubricant material can be disposed on either or both sides of the substrate. In the spatial light modulator as shown in FIG. 1, lubricant material 103 (can be in solid, amorphous, or liquid state) is disposed on the glass substrate 102 on which micromirror array 106 is formed. In a situation where the micromirror array is formed on the semiconductor substrate 104, the lubricant material can be disposed on the semiconductor substrate (not shown in the figure).

The lubricant material can be disposed on the substrate in any desired form. For example, the lubricant material on the substrate may form a ring as shown in the figure. Alternatively, the lubricant on the substrate can be provided as strips or discontinuous segments with a gap in between.

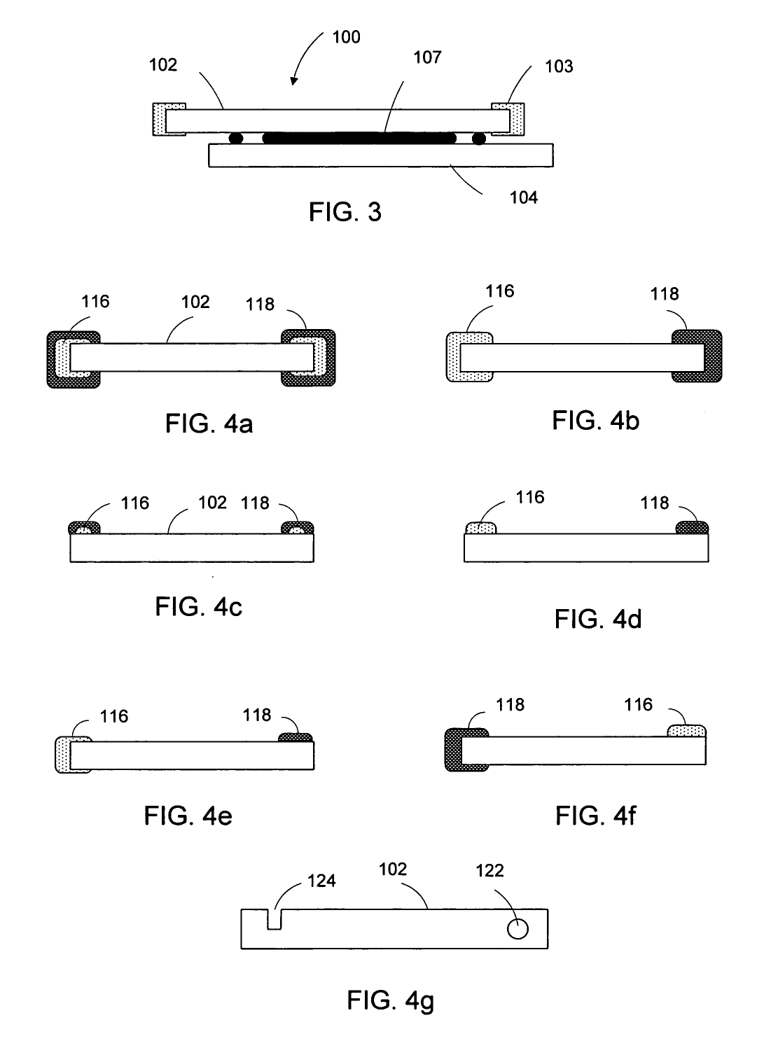

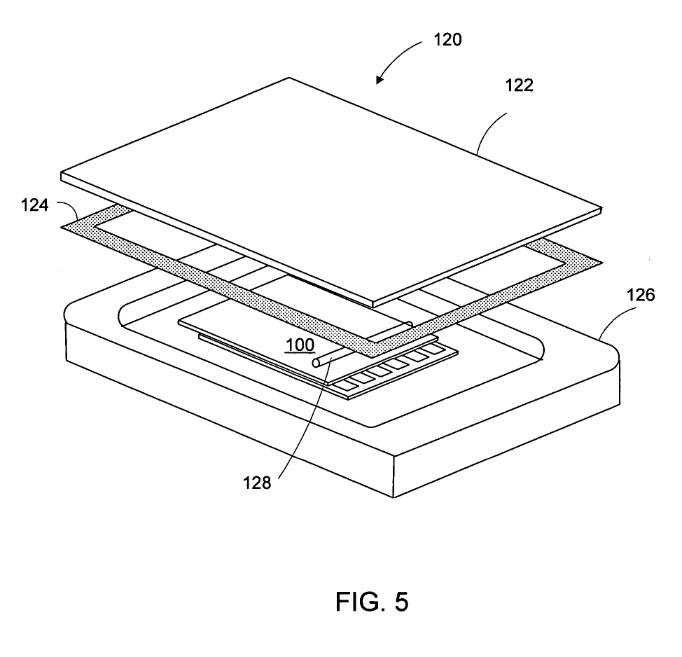

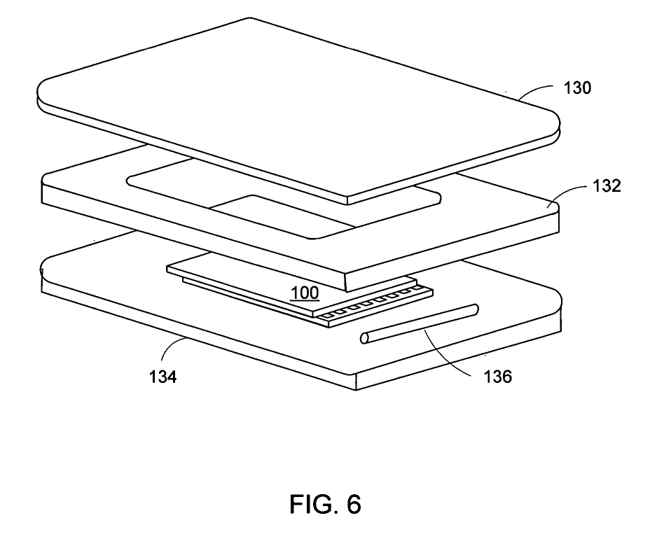

The getter material can be deposited on the substrate on which the deflectable elements are formed in the same way as the lubricant. Specifically, the getter material can be deposited on either surface of the substrate and around the circumference of the substrate either continuously or discontinuously. Selected getter material (e.g. if in black color) may also be employed for absorbing scattered light from the edges of the micromirror device, in which situation the getter material can be disposed around the periphery of the micromirror array. Other nonexclusive exemplary disposure of the lubricant and getter material are illustrated in FIGS. 3 to 4g.

Referring to FIG. 3, a cross-sectional view of the micromirror device in FIG. 1 is illustrated therein. Glass substrate 102 on which the micromirrors are formed is bonded to semiconductor substrate 104 having thereon electrodes and circuitry via bonding material 107. Lubricant and getter material 103 are disposed around the circumference of the glass substrate. The lubricant and/or the getter materials may cover the upper (and/or the lower) surface area around the circumference of the glass substrate, and/or the side-walls of the glass substrate.

As shown in FIG. 4a, lubricant material 116 and getter material 118 may cover the upper and the lower surfaces around the circumference of the glass substrate and the side-walls of the substrate. Alternative to the disposure in FIG. 4a, the lubricant material may cover only a partial upper/lower surfaces around the circumference of the substrate, while the getter material covers partial or all the remaining upper/lower surfaces around the circumference of the substrate, as shown in FIG. 4b. A high surface area getter may be used to hold the lubricant, e.g. by surrounding the lubricant or by holding the lubricant as a “sponge.”

Referring to FIG. 4c an 4d, the lubricant and the getter materials may be deposited on a surface (can be the upper or the lower surface) of the substrate on which the micromirrors are formed. In the example shown in FIG. 4c, the lubricant and the getter materials cover a surface around the circumference of the substrate. Alternatively, the lubricant material may cover only a portion of a surface (e.g. upper or lower surface) around the circumference of the substrate, and the getter material covers a portion or all the remaining area of the surface around the circumference of the substrate, as shown in FIG. 4d.

Referring to FIG. 4e, lubricant material 116 may be deposited on the upper and lower surfaces around the circumference of the substrate and the side-walls of the substrate, while getter material 116 is deposited on a surface (e.g. the upper or lower surface) of the substrate on which the micromirrors are formed. Alternatively, getter material 118 may be deposited on the upper and lower surfaces around the circumference of the substrate and the side-walls of the substrate, while lubricant material 116 is deposited on a surface (upper or lower surface) of the substrate on which the micromirrors are formed, shown in FIG. 4f.

The lubricant and the getter materials can also be held by a wall or a container, especially when the lubricant material is liquid. As an example of the invention, the substrate on which the micromirrors are formed has thereon one or more cavities for holding the lubricant and getter materials. The cavity can be a trench or tubing formed on the substrate, as shown in FIG. 4g. Referring to FIG. 4g, the substrate, such as glass substrate 102 having the micromirrors has trench 124 and tubing 122. The trench and tubing can be separately formed on either surface or the side-walls of the substrate. The sizes of the trench and tubing are preferably determined by the desired amount of the getter and lubricant materials because too little lubricant will nor prevent stiction, while too much lubricant will create excessive capillary adhesion. As a benefit, the amount of the lubricant introduced onto the surfaces to be lubricated can be precisely controlled. For example, the amount of the lubricant and the interior volume of the tubing for containing the lubricant are of from 10 pico-liters to 10 micro-liters or from 30 pico-liters to 2 micro-liters.

In another example of the invention, separate containers can be provided for holding the lubricant and getter materials. For example, a capillary tubing can be provide for holding the lubricant, as set forth in US patent application “A METHOD AND APPARATUS FOR LUBRICATING MICROELECTROMECHANICAL DEVICES IN PACKAGES”, attorney docket number P132-US, filed along with the current patent application, the subject matter being incorporated herein by reference. The containers for holding the lubricant and/or the getter materials can be affixed to the substrate on which the microstructures are formed. For example, the container having the lubricant material can be attached to a surface or side-wall of the substrate on which the micromirrors are formed, while the getter material can be deposited on the substrate without using a container.

In yet another example, the lubricant can be physically adsorbed on a carrier material that is attached to the substrate having the micromirrors. Before or during the operation of the micromirrors, the carrier material desorbs the lubricant so as to lubricant the surfaces to be lubricated. In this situation, the carrier material can be a porous material in solid state. The carrier material may also be provided with other control mechanisms, such as an electromagnetic coil that generates heat for heating the carrier material when the coil is powered. The heated carrier material desorbs the lubricant for lubricating the targeted surfaces. With this configuration, an amount of lubricant materials in either liquid, solid, amorphous or vapor phase can be adsorbed to the carrier material, preferably in solid state having any desired shape, such as a strip or a shim. The carrier material is then attached to the substrate having the micromirrors. At any desired time, the control mechanism of the carrier material can be powered so as to activate the carrier material to desorb the lubricant.

When a container is provided for holding the lubricant or the getter material, the container may be employed for absorbing scattered light. For example, the container can be a black color and disposed on the substrate having the micromirrors and around the micromirror array when viewed from the top of the substrate.

In general, the spatial light modulator is packaged before delivery to customers. An exemplary spatial light modulator package is illustrated in FIG. 5. As shown in the figure, spatial light modulator 100 is attached to package substrate 126. The package substrate may take any desired shape and form and may comprise any suitable material. In this particular example, the package substrate is a ceramic and has a cavity in which the microelectromechanical device can be disposed. A separate lubricant container 128 (other than the lubricant container attached to the substrate having the micromirrors) can be provided and placed on the package substrate at a location proximate to the spatial light modulator. The container contains a lubricant that evaporates from the container to the surface of the micromirrors of the spatial light modulator for lubricating the surface. In order to seal the package, package cover 122 is provided and sealing material 124 is disposed between the package substrate and the package cover for bonding the package substrate and the package cover. The sealing material can be deposited on the top surface of the package substrate or on the bottom surface of the package cover, or alternatively, on both.

The spatial light modulator can be packaged in many other methods. Another exemplary spatial light modulator package is illustrated in FIG. 6. Referring to FIG. 6, package substrate 134 is a flat substrate. Spatial light modulator 100 is attached to the package substrate. Container 136 having the lubricant (or a mixture of the lubricant and a diluent) is place close to the spatial light modulator on substrate 134. Spacer 132 is disposed on the flat substrate 134 so as to form a cavity for accommodating the microelectromechanical device. Package cover 130 is placed on the spacer and the package substrate. The spacer and the package substrate and the spacer and the package cover can be bonded and hermetically sealed using proper sealing material such as solder or glass frit.

It will be appreciated by those of skill in the art that a new and useful method and apparatus for lubricating microelectromechanical devices have been described herein. In view of many possible embodiments to which the principles of this invention may be applied, however, it should be recognized that the embodiments described herein with respect to the drawing figures are meant to be illustrative only and should not be taken as limiting the scope of invention. For example, those of skill in the art will recognize that the illustrated embodiments can be modified in arrangement and detail without departing from the spirit of the invention. Therefore, the invention as described herein contemplates all such embodiments as may come within the scope of the following claims and equivalents thereof.

1. A packaged microelectromechanical device, comprising:
a deflectable element on a substrate;
a getter material and/or a lubricant material disposed on the substrate; and
a package having the substrate with the deflectable element.

2. The device of claim 1, wherein the substrate is glass substrate that is transmissive to visible light.

3. The device of claim 2, wherein the deflectable element is a mirror plate that is attached to a hinge formed on the substrate such that the mirror plate can rotate on the substrate.

4. The device of claim 1, wherein the substrate is a semiconductor substrate having thereon an electrode and circuitry for detecting the deformable element.

5. The device of claim 1, wherein the package further comprises:
a package substrate having a cavity in which the substrate and the deflectable element is accommodated; and
a cover lid on the package substrate.

6. The device of claim 5, wherein the cover lid is glass that is transmissive to visible light.

7. The device of claim 5, wherein the cover lid has a window that passes visible light.

8. The device of claim 5, wherein the package substrate is a flat substrate that is bonded to the cover lid through a spacer disposed therebetween.

9. The device of claim 1, wherein the lubricant material is disposed on a surface around the circumference of the substrate.

10. The device of claim 1, wherein the lubricant material is disposed on a side-wall of the substrate.

11. The device of claim 1, wherein the lubricant is disposed in a capillary tubing formed on the substrate.

12. The device of claim 11, wherein the tubing has a size that is determined by a desired amount of lubricant.

13. The device of claim 11, wherein the tubing has an opening on a surface of substrate.

14. The device of claim 11, wherein the tubing has an opening on a side-wall of substrate.

15. The device of claim 1, wherein the lubricant is held by a container that is attached affixed to the substrate having the deflectable element.

16. The device of claim 1, wherein the lubricant is disposed in a trench on the substrate.

17. The device of claim 1, further comprising: a getter.

18. The device of claim 1, further comprising: a lubricant.

19. The device of claim 1, further comprising: a getter and a lubricant.

20. A microelectromechanical device, comprising:
a substrate;
a deflectable element attached to a deformable element held by the substrate; and
a carrier disposed on the substrate, wherein the carrier adsorbs a lubricant material that is operable for lubricating a surface of the device, said carrier is operable to desorb the adsorbed lubricant upon a variation of the environment in which the device is operated.

21. A packaged microelectromechanical device, comprising:
a deflectable element on a substrate;
a getter having a getter material disposed on the substrate;
a lubricant material that is carried by the getter; and
a package having the substrate with the deflectable element.

22. The device of claim 21, wherein the substrate is glass substrate that is transmissive to visible light.

23. The device of claim 22, wherein the deflectable element is a mirror plate that is attached to a hinge formed on the substrate such that the mirror plate can rotate on the substrate.

24. The device of claim 21, wherein the substrate is a semiconductor substrate having thereon an electrode and circuitry for deflecting the deformable element.

25. The device of claim 21, wherein the package further comprises:
a package substrate having a cavity in which the substrate and the deflectable element is accommodated; and
a cover lid on the package substrate.

26. The device of claim 25, wherein the cover lid is glass that is transmissive to visible light.

27. The device of claim 25, wherein the cover lid has a window that passes visible light.

28. The device of claim 25, wherein the package substrate is a flat substrate that is bonded to the cover lid through a spacer disposed therebetween.

29. The device of claim 21, wherein the lubricant material is disposed on a surface around the circumference of the substrate.

30. The device of claim 21, wherein the lubricant material is disposed on a side-wall of the substrate.

31. The device of claim 21, wherein the lubricant is disposed in a capillary tubing formed on the substrate.

32. The device of claim 31, wherein the tubing has a size that is determined by a desired amount of lubricant.

33. The device of claim 31, wherein the tubing has an opening on a surface of substrate.

34. The device of claim 31, wherein the tubing has an opening on a side-wall of substrate.

35. The device of claim 21, wherein the lubricant is held by a container that is attached affixed to the substrate having the deflectable element.

36. The device of claim 21, wherein the lubricant is disposed in a trench on the substrate.

37. The device of claim 21, further comprising: a getter.

38. The device of claim 21, further comprising: a lubricant.

39. The device of claim 21, further comprising: a getter and a lubricant.
